(19) United States
(12) Patent Application Publication
(10) Pub. No.: US 2024/0373694 A1
(43) Pub. Date: Nov. 7, 2024

(54) DISPLAY DEVICE

(71) Applicant: Samsung Display Co., Ltd., Yongin-Si, Gyeonggi-Do (KR)

(72) Inventor: CHANYOON WOO, Yongin-Si, Gyeonggi-Do (KR)

(21) Appl. No.: 18/439,688

(22) Filed: Feb. 12, 2024

(30) Foreign Application Priority Data
Apr. 23, 2023 (KR) 10-2023-0044952

(51) Int. Cl. H10K 59/131; H10K 59/40

(52) U.S. Cl. CPC H10K 59/131; H10K 59/40

(57) ABSTRACT

A display device includes a display panel that includes a plurality of display pads, and a circuit board. The circuit board includes a base layer, a first circuit wiring disposed on the base layer and that partially extends in a first direction, a first insulating layer that covers the first circuit wiring, a second circuit wiring disposed on the first insulating layer and that partially extends in the first direction, a second insulating layer that covers the second circuit wiring, and a plurality of circuit pads disposed on the second insulating layer and electrically connected to the plurality of display pads. A first side of the first circuit wiring overlaps a portion of an upper surface of the second circuit wiring, or a second side of the second circuit wiring overlaps a portion of an upper surface of the first circuit wiring.

### CROSS-REFERENCE TO RELATED APPLICATIONS

This U.S. non-provisional patent application claims priority under 35 U.S.C. § 119 from Korean Patent Application No. 10-2023-0044952, filed on Apr. 5, 2023 in the Korean Intellectual Property Office, the contents of which are herein incorporated by reference in their entirety.

### TECHNICAL FIELD

Embodiments of the present disclosure are directed to a display device, and more particularly, to a display device that includes a circuit board.

### DISCUSSION

Display devices typically include a display module that includes an active region to be activated and an inactive region. The display module includes a display panel that displays images to users and an input circuit that senses user inputs. The display panel and the input circuit receive external signals or transmit generated signals. The display panel and the input circuit may transmit or receive electrical signals through a circuit board. Signal lines or driving elements are disposed on the circuit board. As display devices can have various shapes, circuit boards used in the display devices also have various shapes.

### SUMMARY

Embodiments of the present disclosure provide a display device that includes a circuit board that has at least one flat surface.

An embodiment of the inventive concept provides a display device that includes a display panel that includes a plurality of display pads, and a circuit board electrically connected to the display panel. The circuit board includes a base layer, a first circuit wiring disposed on the base layer and that at least partially extends in a first direction, a first insulating layer that covers the first circuit wiring, a second circuit wiring disposed on the first insulating layer and that at least partially extends in the first direction, a second insulating layer that covers the second circuit wiring, and a plurality of circuit pads disposed on the second insulating layer and electrically connected to the plurality of display pads. A first side of the first circuit wiring overlaps at least a portion of an upper surface of the second circuit wiring, or a second side of the second circuit wiring overlaps at least a portion of an upper surface of the first circuit wiring.

In an embodiment, the first side is not vertically aligned with the corresponding second side.

In an embodiment, the first side includes a (1-1)-th side and a (1-2)-th side that faces the (1-1)-th side in a second direction that crosses the first direction, the second side includes a (2-1)-th side and a (2-2) side that faces the (2-1)-th side in the second direction, the (1-1)-th side and the (2-1)-th side are not vertically aligned, and the (1-2)-th side and the (2-1)-th are not vertically aligned.

In an embodiment, an imaginary center line of the first circuit wiring parallel to the first direction does not overlap an imaginary center line of the second circuit wiring parallel to the first direction.

In an embodiment, a width in a second direction that crosses the first direction of the first circuit wiring differs from a width in the second direction of the second circuit wiring.

In an embodiment, the circuit board further includes a lower insulating layer disposed between the base layer and the first insulating layer, and a third circuit wiring disposed on the lower insulating layer, and a third side of the lower insulating layer is not vertically aligned with the first side or the second side.

In an embodiment, the third side overlaps at least a portion of the upper surface of the first circuit wiring or the upper surface of the second circuit wiring.

In an embodiment, one end of each of the first circuit wiring and the second circuit wiring is connected to the circuit pad.

In an embodiment, the circuit board further includes a planarization layer disposed between the first insulating layer and the second insulating layer, and the planarization layer includes copper.

In an embodiment, the first circuit wiring may include a (1-1)-th circuit wiring and a (1-2)-th circuit wiring spaced apart from the (1-1)-th circuit wiring in a second direction that crosses the first direction, and the second circuit wiring includes a (2-1)-th circuit wiring and a (2-2)-th circuit wiring spaced apart from the (2-1)-th circuit wiring in the second direction.

In an embodiment, a shortest distance in the second direction between the (1-1)-th circuit wiring and the (1-2)-th circuit wiring differs from a shortest distance in the second direction between the (2-1)-th circuit wiring and the (2-2)-th circuit wiring.

In an embodiment, the circuit board further includes a first ground wiring disposed on the base layer and spaced apart from the first circuit wiring, and a second ground wiring disposed on the first insulating layer and spaced apart from the second circuit wiring.

In an embodiment, the first ground wiring includes a (1-1)-th ground wiring and a (1-2)-th ground wiring spaced apart from the (1-1)-th ground wiring, and the second ground wiring includes a (2-1)-th ground wiring and a (2-2)-th ground wiring spaced apart from the (2-1)-th ground wiring.

In an embodiment, the display device further includes an input sensor disposed on the display panel and that includes a sensing electrode. Each of the (1-1)-th ground wiring and the (2-1)-th ground wiring is connected to the display panel, and each of the (1-2)-th ground wiring and the (2-2)-th ground wiring is connected to the input sensor.

In an embodiment, an imaginary center line of a separation space located between the (1-1)-th ground wiring and the (1-2)-th ground wiring and that extends parallel to the first direction does not overlap an imaginary center line of a separation space located between the (2-1)-th ground wiring and the (2-2)-th ground wiring and that extends parallel to the first direction when viewed on a plane.

In an embodiment, a shortest distance in a second direction that crosses the first direction between the (1-1)-th ground wiring and the (1-2)-th ground wiring differs from a shortest distance in the second direction between the (2-1)-th ground wiring and the (2-2)-th ground wiring.

In an embodiment, the display panel includes a first non-bendable region that includes a display region, a second non-bendable region, and a bendable region disposed between the first non-bendable region and the second non-bendable region and that has a predetermined radius of curvature. The circuit board overlaps the second non-bendable region.

In an embodiment, each of the first circuit wiring and the second circuit wiring includes copper, and each of the first insulating layer and the second insulating layer includes polyimide (PI).

In an embodiment of the inventive concept, a display device includes a display panel, and a circuit board electrically connected to the display panel. The circuit board includes a base layer, a first circuit wiring disposed on the base layer and that extends in a first direction, a first insulating layer that covers the first circuit wiring, a second circuit wiring disposed on the first insulating layer and that extends in the first direction, and a second insulating layer that covers the second circuit wiring. An imaginary center line of the first circuit wiring that extends parallel to the first direction does not overlap an imaginary center line of the second circuit wiring that extends parallel to the first direction.

### BRIEF DESCRIPTION OF THE FIGURES

FIG. 1 is a perspective view of a display device according to an embodiment of the inventive concept.

FIG. 2 is an exploded perspective view of a display device according to an embodiment of the inventive concept.

FIG. 3 is a cross-sectional view of a display module according to an embodiment of the inventive concept.

FIG. 4A is a plan view of a display panel according to an embodiment of the inventive concept.

FIG. 4B is a plan view of an input sensor according to an embodiment of the inventive concept.

FIG. 5 is a plan view of some components of a display device according to an embodiment of the inventive concept.

FIG. 6 is an exploded perspective view of a display panel and a circuit board according to an embodiment of the inventive concept.

FIG. 7A is a cross-sectional view of a partial region of a circuit board according to an embodiment of the inventive concept.

FIG. 7B is a plan view of a partial region of a first layer according to an embodiment of the inventive concept.

FIG. 7C is a plan view of a partial region of a second layer according to an embodiment of the inventive concept.

FIGS. 8A and 8B are each a cross-sectional view of a partial region of a circuit board according to an embodiment of the inventive concept.

FIG. 9A is a cross-sectional view of a different partial region of a circuit board according to an embodiment of the inventive concept.

FIG. 9B is a plan view of a different partial region of a first layer according to an embodiment of the inventive concept.

FIG. 9C is a plan view of a different partial region of a second layer according to an embodiment of the inventive concept.

FIG. 10 is a cross-sectional view of a partial region of a circuit board according to a Comparative Example.

### DETAILED DESCRIPTION

As used herein, when an element, a region, a layer, a portion, etc., is referred to as being “on,” “connected to,” or “bonded to” another element, it means that the element may be directly disposed on/connected to/bonded to the other element, or that a third element may be disposed therebetween.

Like reference numerals may refer to like elements.

Hereinafter, embodiments of the inventive concept will be described with reference to the accompanying drawings.

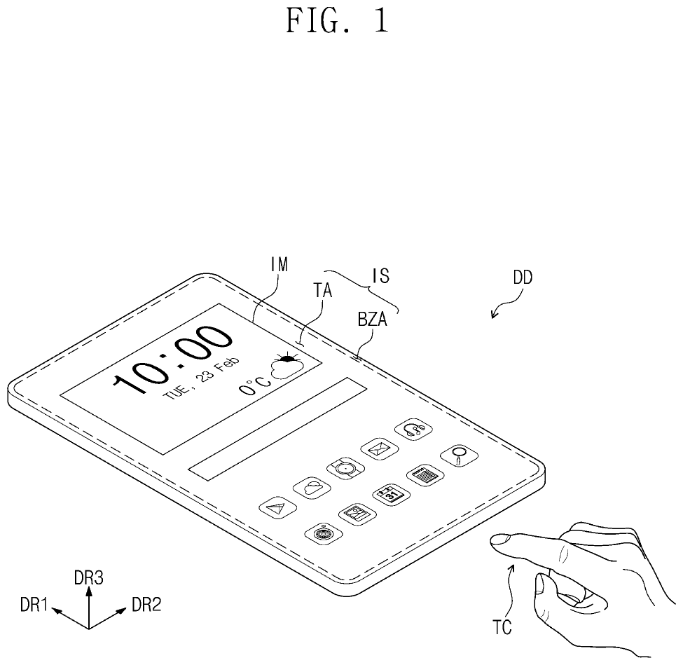

FIG. 1 is a perspective view of a display device DD according to an embodiment of the inventive concept.

Referring to FIG. 1, the display device DD has a rectangular shape that includes a short side parallel to a first direction DR1 and a long side parallel to a second direction DR2, where the second direction DR2 crosses the first direction DR1. However, the shape of the display device DD is not necessarily limited thereto.

FIG. 1 shows that the display device DD is a smartphone, but is not necessarily limited thereto, and the display device DD according to an embodiment of the inventive concept can not only include large-sized display devices such as a television set and a monitor, but also small- and medium-sized display devices such as a car navigation system and a game console.

As shown in FIG. 1, the display device DD includes a display surface IS parallel to each of the first direction DR1 and the second direction DR2. The display surface IS displays an image IM toward a third direction DR3 that is normal to a plane defined by the first and second directions DR1 and DR2. The display surface IS on which the image IM is displayed corresponds to a front surface of the display device DD. The image IM can include still images as well as moving images.

In a present embodiment, a front surface (or an upper surface) and a rear surface (or a lower surface) of respective members are defined with respect to the third direction DR3 in which the image IM is displayed. The front and rear surfaces oppose each other in the third direction DR3 and a normal direction of each of the front and rear surfaces is parallel to the third direction DR3.

A distance between the front surface and the rear surface in the third direction DR3 corresponds to a thickness in the third direction DR3 of the display device DD. However, directions indicated by the first to third directions DR1, DR2, and DR3 are relative concepts, and can be changed to other directions.

The front surface of the display device DD is divided into a transmission region TA and a bezel region BZA. The transmission region TA is where the image IM is displayed. Users view the image IM through the transmission region TA. In a present embodiment, the transmission region TA has a rectangular shape that has rounded corners. However, embodiments are not necessarily limited thereto, and in other embodiments, the transmission region TA can have various other shapes.

The bezel region BZA is adjacent to the transmission region TA. The bezel region BZA may have a predetermined color. The bezel region BZA surrounds the transmission region TA. Accordingly, the shape of the transmission region TA is substantially defined by the bezel region BZA. However, embodiments are not necessarily limited thereto, and in other embodiments, the bezel region BZA may be adjacent to only one side of the transmission region TA or omitted. The display device DD according to an embodiment of the inventive concept may be implemented in various embodiments and is not necessarily limited to any one embodiment.

The display device DD according to an embodiment of the inventive concept can sense an externally applied user input TC. For example, the user input TC can include various types of external inputs, such as a portion of the user's body, light, heat, or pressure. In a present embodiment, the user input TC is shown as a user's hand applied to the front surface. However, embodiments are not necessarily limited thereto, and as described above, in other embodiments, the user input TC can take other forms, and the user input TC applied to a side surface or the rear surface of the display device DD can be sensed, depending on the structure of the display device DD.

The display device DD activates the display surface IS to display the image IM and sense the user input TC. According to an embodiment, a region that senses the user input TC is provided in the transmission region TA. However, embodiments of the inventive concept are not necessarily limited thereto, and in other embodiments, the user input TC sensing region may be provided in the bezel region BZA or the entire region of the display surface IS.

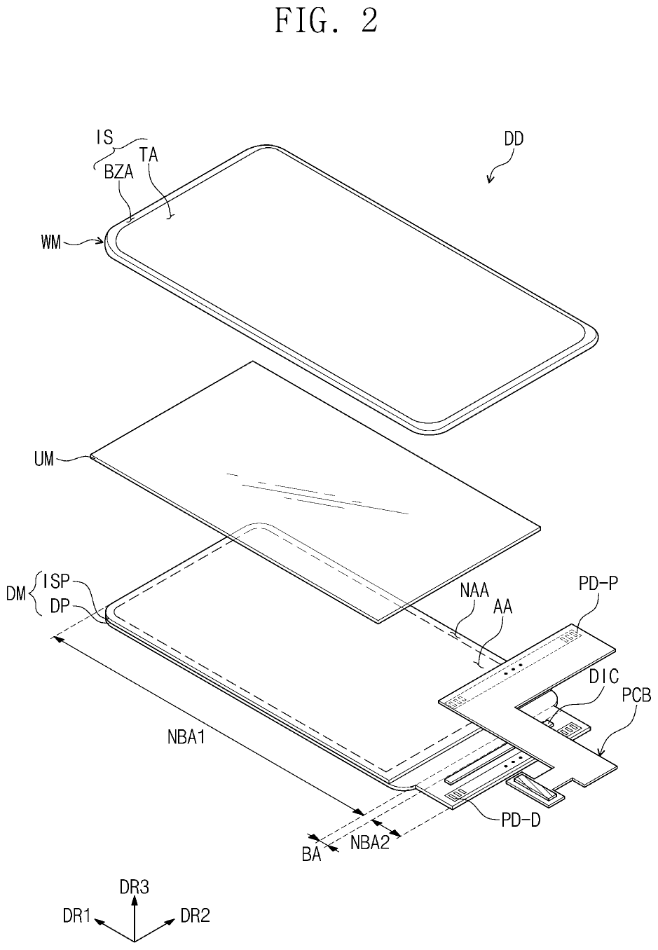

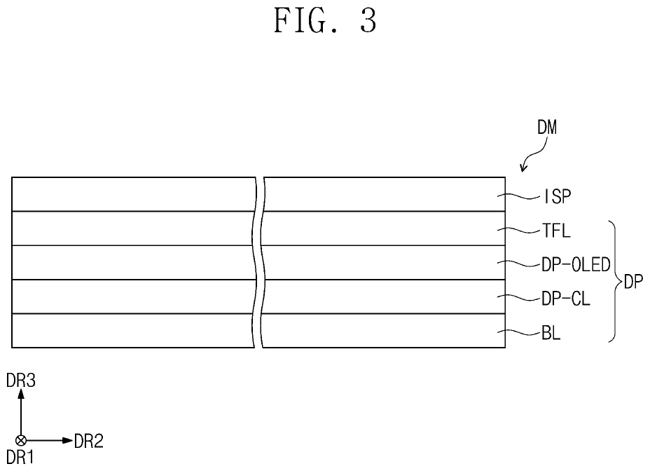

FIG. 2 is an exploded perspective view of a display device DD according to an embodiment of the inventive concept. FIG. 3 is a cross-sectional view of a display module DM according to an embodiment of the inventive concept.

Referring to FIG. 2, the display device DD according to an embodiment of the inventive concept includes a window WM, an upper member UM, a display module DM, and a circuit board PCB.

The window WM is formed of a transparent material that can emit images. For example, the window WM is formed of at least one of glass, sapphire, or plastic, etc. The window WM is shown as a single layer, but is not necessarily limited thereto, and may include a plurality of layers. The bezel region BZA of the display device DD is where a material that includes a predetermined color is printed on one region of the window WM.

The upper member UM is interposed between the display module DM and the window WM. The upper member UM includes an anti-reflection layer that blocks reflection of external light. The upper member UM can prevent elements of the display module DM from being viewed from the outside due to external light incident through the front surface of the display device DD. The upper member UM includes a retarder and a polarizer. The retarder may be a film type or a liquid crystal coating type, and includes a λ/2 retarder and/or a λ/4 retarder. The polarizer may also be a film type or a liquid crystal coating type. The film type includes an elongated synthetic resin film, and the liquid crystal coating type includes liquid crystals in a predetermined arrangement. The retarder and the polarizer may be implemented as one polarizing film. The upper member UM also includes an anti-reflection layer and further includes a protection film disposed above or below the anti-reflection layer.

In addition, an adhesive film is further disposed between the display module DM and the upper member UM. The adhesive film includes one of an optically clear adhesive film (OCA), an optically clear resin (OCR), or a pressure sensitive adhesive film (PSA).

The display module DM includes a display panel DP and an input sensor ISP disposed on the display panel DP. The display panel DP generates images, and the input sensor ISP obtains coordinate information on user inputs, such as a touch event.

The display module DM includes an active region AA and a peripheral region NAA. The active region AA is where images are output from the display module DM. The peripheral region NAA is adjacent to the active region AA. For example, the peripheral region NAA surrounds the active region AA. However, embodiments are not necessarily limited thereto, and in other embodiment, the peripheral region NAA has various other shapes. According to an embodiment, the active region AA of the display module DM corresponds to at least a portion of the transmission region TA.

According to an embodiment, the display panel DP includes a first non-bendable region NBA1, a bendable region BA, and a second non-bendable region NBA2 that are sequentially arranged in the first direction DR1. The bendable region BA is a portion that can be bent with respect to a predetermined axis that extends in the second direction DR2. When the bendable region BA is bent, the second non-bendable region NBA2 is disposed below the first non-bendable region NBA1.

The first non-bendable region NBA1 of the display panel DP includes the active region AA. A region of the first non-bendable region NBA1 other than the active region AA, the bendable region BA, and the second non-bendable region NBA2 corresponds to the peripheral region NAA.

A driving element DIC that can drive the display panel DP is mounted in the second non-bendable region NBA2 of the display panel DP. A display pad PD-D is disposed adjacent to an end of the second non-bendable region NBA2 of the display panel DP. The circuit board PCB is disposed at an end portion of the second non-bendable region NBA2 of the display panel DP. However, embodiments of the inventive concept are not necessarily limited thereto, and in other embodiments, the driving element DIC is mounted on the circuit board PCB.

The circuit board PCB transmits power signals or signals that control the image IM (see FIG. 1) from a main board in the display device DD to the display panel DP. The circuit board PCB is a flexible circuit board. The circuit board PCB includes a circuit pad PD-P disposed adjacent to an end. The circuit pad PD-P is connected to the display pad PD-D. Accordingly, the circuit board PCB and the display module DM are electrically connected.

In addition, the display device DD further includes a functional layer disposed below the display module DM. The functional layer may be a metal layer or a cushion layer. The metal layer supports the display module DM. The cushion layer includes a polymer material that absorbs externally applied shocks. In addition, the functional layer may further include an adhesive layer.

Referring to FIG. 3, the display module DM according to an embodiment includes the display panel DP and the input sensor ISP disposed on the display panel DP.

The display panel DP generates images. The display panel DP according to an embodiment of the inventive concept is a light emitting display panel, but is not particularly limited. For example, the display panel DP may be an organic light emitting display panel or a quantum dot light emitting display panel. An emission layer of the organic light emitting display panel includes an organic light emitting material. An emission layer of the quantum dot light emitting display panel includes quantum dots or quantum rods, etc. Hereinafter, the display panel DP according to an embodiment is described as an organic light emitting display panel. The display panel DP according to an embodiment is a flexible display panel, and thus, the display panel DP can be entirely rolled or folded.

The display panel DP includes a base substrate BL, a circuit layer DP-CL, a light emitting element layer DP-OLED, and an encapsulation layer TFL.

The base substrate BL includes a synthetic resin layer. The base substrate BL may have a multilayer structure. For example, the base substrate BL has a three-layer structure of a synthetic resin layer, an adhesive layer, and a synthetic resin layer. For example, the synthetic resin layer is a polyimide-based resin layer, but the material is not particularly limited. The synthetic resin layer includes at least one of an acryl-based resin, a methacryl-based resin, polyisoprene, a vinyl-based resin, an epoxy-based resin, a urethane-based resin, a cellulose-based resin, a siloxane-based resin, a polyamide-based resin, or a perylene-based resin. In addition, the base substrate BL includes a glass substrate or an organic/inorganic composite material substrate.

The circuit layer DP-CL is disposed on the base substrate BL. The circuit layer DP-CL includes an insulating layer, a semiconductor pattern, a conductive pattern, a signal line, etc. The insulating layer, the semiconductor layer, and the conductive layer are formed on the base substrate BL, through methods such as coating or vapor deposition, and then the insulating layer, the semiconductor layer, and the conductive layer are selectively patterned multiple times by a photolithography process. Accordingly, a semiconductor pattern, a conductive pattern, and a signal line of the circuit layer DP-CL can be formed.

The light emitting element layer DP-OLED may be disposed on the circuit layer DP-CL. The light emitting element layer DP-OLED includes light emitting elements. For example, the light emitting element layer DP-OLED includes one of organic light emitting materials, quantum dots, quantum rods, or micro LEDs.

The encapsulation layer TFL is disposed on the light emitting element layer DP-OLED. The encapsulation layer TFL includes an inorganic layer, an organic layer, and an inorganic layer that are sequentially stacked, but the layers that form the encapsulation layer TFL are not necessarily limited thereto.

The inorganic layers protect the light emitting element layer DP-OLED from moisture and oxygen, and the organic layer protects the light emitting element layer DP-OLED from foreign substances such as dust particles. The inorganic layers include at least one of a silicon nitride layer, a silicon oxy nitride layer, a silicon oxide layer, a titanium oxide layer, or an aluminum oxide layer. The organic layer includes an acryl-based organic layer, but is not necessarily limited thereto.

The input sensor ISP is disposed on the display panel DP. In an embodiment, the input sensor ISP is directly disposed on the display panel DP. For example, the input sensor ISP is formed on the display panel DP through a roll-to-roll process. As used herein, “directly disposed” indicates that no third component is disposed between the input sensor ISP and the display panel DP.

However, embodiments of the inventive concept are not necessarily limited thereto. For example, in an embodiment, an adhesive film is disposed between the input sensor ISP and the display panel DP. For example, the input sensor ISP is not manufactured along with the display panel DP through a roll-to-roll process, and after being manufactured by a separate process from the display panel DP, the input sensor ISP is disposed on an upper surface of the display panel DP through an adhesive film.

The input sensor ISP senses external inputs. The external inputs can be user inputs. The user inputs include various types of external inputs, such as a user's body part, light, heat, pen, or pressure.

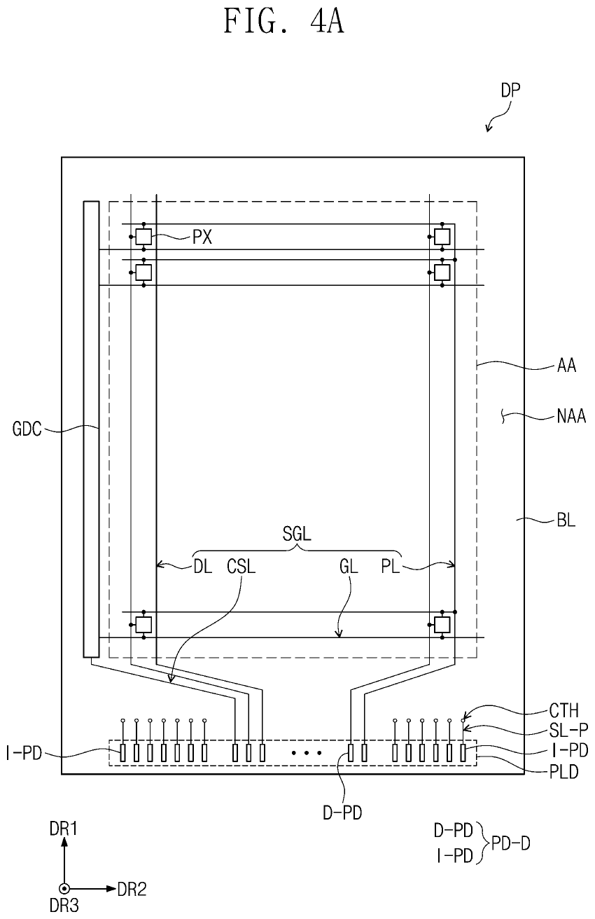

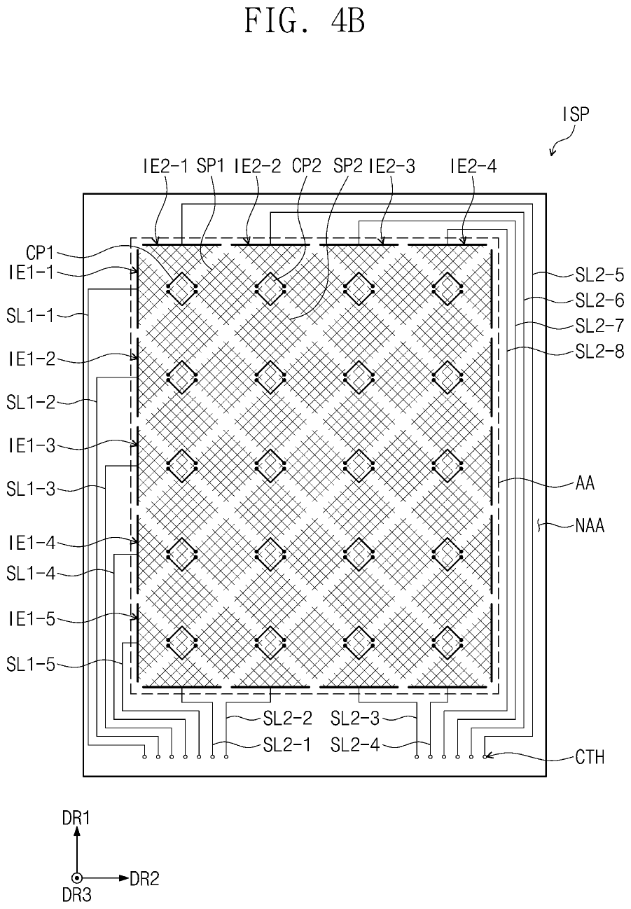

FIG. 4A is a plan view of a display panel according to an embodiment of the inventive concept. FIG. 4B is a plan view of an input sensor according to an embodiment of the inventive concept.

Referring to FIG. 4A, in an embodiment, the display panel DP includes a driving circuit GDC, a plurality of signal lines SGL, and a plurality of pixels PX. The display panel DP further includes a display pad PD-D disposed in the peripheral region NAA.

The pixels PX are disposed in the active region AA. Each of the pixels PX includes a light emitting element and a pixel driving circuit connected thereto. In an embodiment, the light emitting element includes an organic light emitting diode. The driving circuit GDC, the signal lines SGL, the display pad PD-D, and the pixel driving circuit are included in the circuit layer DP-CL (see FIG. 2).

The driving circuit GDC includes a gate driving circuit. The gate driving circuit generates a plurality of gate signals and sequentially outputs the gate signals to a plurality of gate lines GL that will be described below. The gate driving circuit further outputs control signals to the pixel driving circuit.

The signal lines SGL include gate lines GL, data lines DL, a power line PL, and a control signal line CSL. One of the gate lines GL is respectively connected to a corresponding pixel PX, and one of the data lines DL is respectively connected to a corresponding pixel PX. The power line PL is connected to each of the pixels PX. The control signal line CSL provides control signals to the driving circuit GDC. The signal lines SGL overlap the active region AA and the peripheral region NAA.

The display pad PD-D is where the circuit board PCB (see FIG. 2) is connected, and includes pixel pads D-PD that electrically connect the circuit board PCB to the display panel DP, and input pads I-PD that electrically connect the circuit board PCB to the input sensor ISP. The pixel pads D-PD and the input pads I-PD are provided when some of the lines disposed in the circuit element layer DP-OLED are exposed by an insulating layer in the circuit element layer DP-OLED.

The pixel pads D-PD are connected to corresponding pixels PX through the signal lines SGL. In addition, the driving circuit GDC is connected to one of the pixel pads D-PD.

Referring to FIG. 4B, the input sensor ISP according to an embodiment of the inventive concept includes first sensing electrodes IE1-1 to IE1-5, first signal lines SL1-1 to SL1-5 connected to the first sensing electrodes IE1-1 to IE1-5, second sensing electrodes IE2-1 to IE2-4, and second signal lines SL2-1 to SL2-4 connected to the second sensing electrodes IE2-1 to IE2-4. In an embodiment of the inventive concept, the input sensor ISP further includes third signal lines SL2-5 to SL2-8 connected to the second sensing electrodes IE2-1 to IE2-4. For example, the second signal lines SL2-1 to SL2-4 are connected to one end of the second sensing electrodes IE2-1 to IE2-4, and the third signal lines SL2-5 to SL2-8 are connected to the other end of the second sensing electrodes IE2-1 to IE2-4.

The first sensing electrodes IE1-1 to IE1-5 and the second sensing electrodes IE2-1 to IE2-4 cross each other. The first sensing electrodes IE1-1 to IE11-5 and the second sensing electrodes IE2-1 to IE2-4 are insulated from each other to form a mutual capacitance. The first sensing electrodes IE1-1 to IE11-5 are arranged in the first direction DR1, and each extends in the second direction DR2. The second sensing electrodes IE2-1 to IE2-4 are arranged in the second direction DR2, and each extend in the first direction DR1.

The first sensing electrodes IE1-1 to IE11-5 each include first sensor portions SP1 and first connection portions CP1 disposed in the active region AA. The second sensing electrodes IE2-1 to IE2-4 each include second sensor portions SP2 and second connection portions CP2 disposed in the active region AA.

FIG. 4B shows the first sensing electrodes IE1-1 to IE11-5 and the second sensing electrodes IE2-1 to IE2-4 according to an embodiment, but the shape thereof is not necessarily limited thereto. In an embodiment of the inventive concept, the first sensing electrodes IE1-1 to IE1-5 and the second sensing electrodes IE2-1 to IE2-4 have a shape with no separation between the sensor portion and the connection portion, such as a bar shape. Although the first sensor portions SP1 and the second sensor portions SP2 are shown as having a rhombus shape as an example, embodiments of the inventive concept are not necessarily limited thereto, and in other embodiments, the first sensor portions SP1 and the second sensor portions SP2 have different polygonal shapes.

The first sensor portions SP1 of one first sensing electrode are arranged along the second direction DR2, and the second sensor portions SP2 of one second sensing electrode are arranged along the first direction DR1. The first connection portions CP1 each connect adjacent first sensor portions SP1, and the second connection portions CP2 each connect adjacent second sensor portions SP2.

The first signal lines SL1-1 to SL1-5 are connected to one end of the first sensing electrodes IE1-1 to IE1-5, respectively. In an embodiment of the inventive concept, the input sensor ISP further includes signal lines connected to the other ends of the first sensing electrodes IE1-1 to IE11-5.

The first signal lines SL1-1 to SL1-5, the second signal lines SL2-1 to SL2-4, and the third signal lines SL2-5 to SL2-8 are disposed in the peripheral region NAA.

As described with reference to FIG. 4A, the input pads I-PD according to an embodiment are provided by wirings disposed on the circuit layer DP-CL (see FIG. 3) of the display panel DP. Accordingly, a portion SL-P, hereinafter referred to as a pad part, of the first to third signal lines SL1-1 to SL1-5 and SL2-1 to SL2-8 of the input sensor ISP shown in FIG. 4A are disposed inside the display panel DP and connected to the input pads I-PD. The pad part SL-P is electrically connected to the first to third signal lines SL1-1 to SL1-5 and SL2-1 to SL2-8 of the input sensor ISP through a contact hole CTH. The input pads I-PD are connected to corresponding sensing electrodes through the pad part SL-P and the first to third signal lines SL1-1 to SL1-5 and SL2-1 to SL2-8.

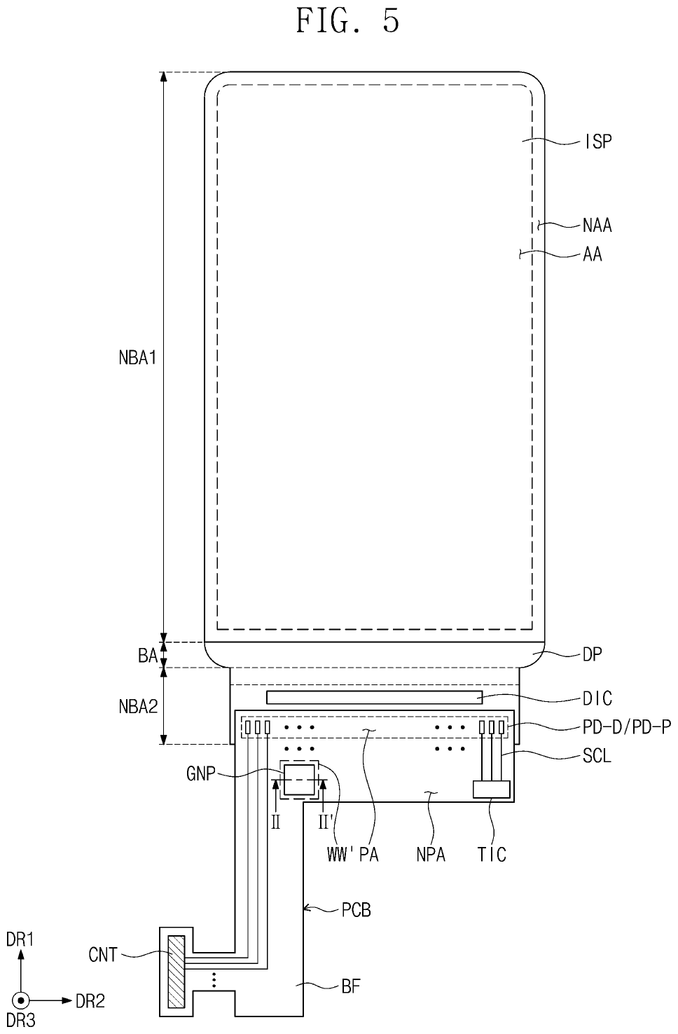

FIG. 5 is a plan view of some components of a display device according to an embodiment of the inventive concept. FIG. 5 shows a state in which the display module DM and the circuit board PCB of the display device DD are attached. Although the display panel DP is not shown as being bent in FIG. 5, in the display device DD according to an embodiment of the inventive concept, the bendable region BA of the display panel DP may be bent. For example, when the bendable region BA of the display panel DP is bent, the second non-bendable region NBA2 of the display panel DP and the circuit board PCB faces a rear surface of the first non-bendable region NBA1 of the display panel DP. In the following description, the same/similar reference numerals are used for the same/similar components of FIGS. 1 to 4B, and redundant descriptions may be omitted.

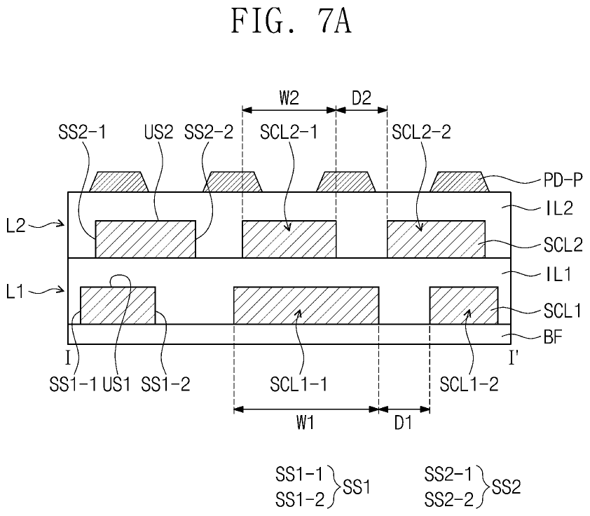

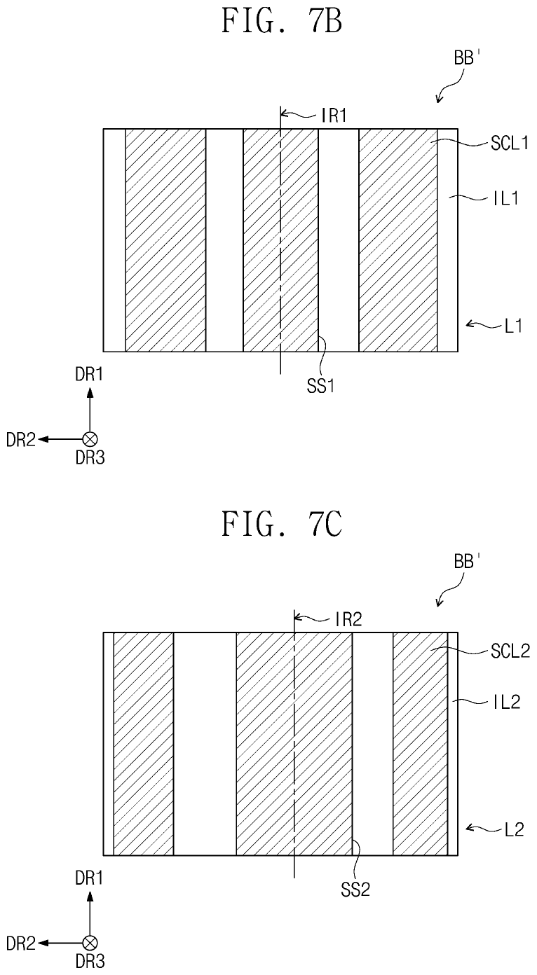

Referring to FIG. 5, the circuit board PCB according to a present embodiment includes a base layer BF, a plurality of elements, a connector CNT, a circuit pad PD-P, circuit wirings SCL, and a ground wiring GNP. However, although an insulating layer is omitted from FIG. 5 for convenience of illustration, the circuit board PCB of an embodiment also includes a plurality of stacked insulating layers, and the plurality of elements, the connector CNT, the circuit wiring SCL, and the ground wiring GNP are stacked on each insulating layer. The insulating layer and the stack structure of the circuit board PCB are described in detail below in FIG. 7A. In addition, the circuit wiring SCL includes first and second circuit wirings SCL1 and SCL2 that are shown and described with reference to FIGS. 7A to 7C, below.

The base layer BF includes an insulating material. The base layer BF includes an organic insulating material, and constituent materials of the base layer BF include polymer materials such as at least one of polyimide (PI), polyethylene terephthalate (PET), or polyethylene naphthalate (PEN). For example, the base layer BF includes polyimide (PI).

The plurality of elements are disposed on the base layer BF. The elements include a resistor, a condenser, an inductor, and a plurality of terminals, as well as a timing controller (TIC) and a voltage generator.

The connector CNT is disposed on the base layer BF. The connector CNT electrically interconnects circuit boards. Therefore, the circuit board PCB is connected to a main board through the connector CNT, and the circuit board PCB electrically connects the display module DM and the main board. The connector CNT is disposed on a portion of the base layer BF that does not overlap the display panel DP. However, the position of the connector CNT is not necessarily limited thereto.

The circuit pad PD-P are disposed on the base layer BF. The circuit board PCB includes a connection region PA and a non-connection region NPA. The connection region PA is where the circuit pad PD-P is mounted on the circuit board PCB. As the circuit pad PD-P of the circuit board PCB and the display pad PD-D of the display panel DP are connected in the connection region PA, the circuit board PCB and the display module DM (see FIG. 2) are electrically connected.

The circuit wiring SCL is disposed on the base layer BF. The circuit wiring SCL includes signal wirings. Some of the signal wirings extend from the circuit pad PD-P to electrically connect the circuit pad PD-P and other elements, or are disposed between elements to electrically connect elements disposed on both ends of each of the signal wirings. In addition, some of the signal lines extend from the circuit pad PD-P to the connector CNT to electrically connect the circuit pad PD-P and the connector CNT. FIG. 5 shows, as an example of the circuit wiring SCL, signal wirings SCL that extend from the circuit pad PD-P and are connected to the timing controller TIC, and signal wirings that extend from the circuit pad PD-P and are connected to the connector CNT.

The ground wiring GNP is disposed on the base layer BF. The ground wiring GNP provides a reference voltage, and thus serves as a ground. The ground wiring GNP provides a reference potential for determining whether the circuit board PCB and elements mounted on the circuit board PCB operate. In addition, the display device DD of an embodiment further includes a cover tape connected to the ground wiring GNP.

According to an embodiment, the circuit wiring SCL and the ground wiring GNP each include a conductive material. The circuit wiring SCL and the ground wiring GNP each include a metal, and, for example, the circuit wiring SCL and the ground wiring GNP each include copper.

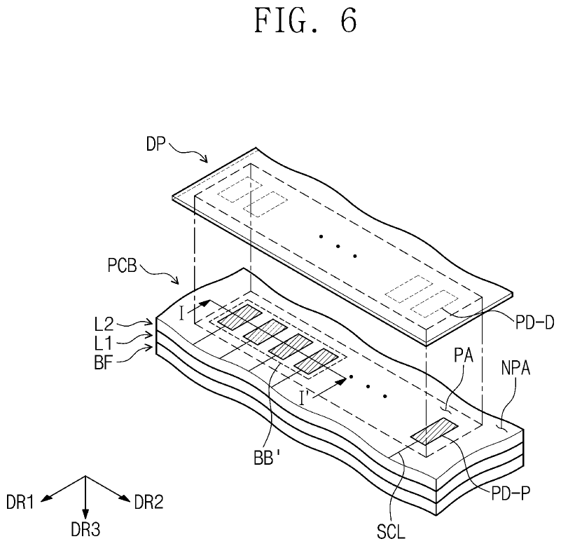

FIG. 6 is an exploded perspective view of a display panel and a circuit board according to an embodiment of the inventive concept. FIG. 6 is an enlarged view of the display panel DP and the circuit board PCB in the connection region PA and shows details thereof. Although each component is shown as being disassembled in FIG. 6, in a display device according to an embodiment, each component is provided in combination. FIG. 7A is a cross-sectional view of a partial region of a circuit board according to an embodiment of the inventive concept. FIG. 7A is a cross section that corresponds to line I-I′ of FIG. 6. FIG. 7B is a plan view of a partial region of a first layer according to an embodiment of the inventive concept, and FIG. 7C is a plan view of a partial region of a second layer according to an embodiment of the inventive concept. FIG. 7B is a plan view of the first layer in region BB′ shown in FIG. 6, and FIG. 7C is a plan view of the second layer in region BB′ shown in FIG. 6. FIGS. 7B and 7C show the relative positions of the first and second circuit wirings SCL1 and SCL2 in each of a first layer L1 and a second layer L2 of the circuit board PCB in the connection region PA in detail.

Referring to FIG. 6, in an embodiment, the circuit board PCB includes the circuit pad PD-P, and the display panel DP includes the display pad PD-D. Since the circuit pad PD-P and the display pad PD-D are in contact, the circuit board PCB and the display panel DP are connected in the connection region PA. Accordingly, the circuit board PCB and the display module DM (see FIG. 2) are electrically connected. The circuit wiring SCL is connected to the circuit pad PD-P of the circuit board PCB.

Referring to FIGS. 6 and 7A, the circuit board PCB includes the base layer BF, a first layer L1 disposed on the base layer BF, a second layer L2 disposed on the first layer L1, and the circuit pad PD-P disposed on the second layer L2.

Each of the first layer L1 and the second layer L2 includes the circuit wiring SCL. The first layer L1 includes the first circuit wiring SCL1, and the second layer L2 includes the second circuit wiring SCL2. Each of the first circuit wiring SCL1 and the second circuit wiring SCL2 is disposed below the circuit pad PD-P. For example, in an embodiment of the inventive concept, at least a portion of the circuit wiring SCL is not disposed on a layer parallel to the circuit pad PD-P, but is disposed below the circuit pad PD-P. Accordingly, in the circuit board PCB according to an embodiment of the inventive concept, a planar region occupied by the circuit wiring SCL is relatively reduced compared to a case where the circuit wiring SCL is entirely disposed on a layer parallel to the circuit pad PD-P. Therefore, the display device DD according to an embodiment of the inventive concept provides a circuit board PCB having a small planar region. In addition, although omitted from FIG. 7A for convenience of illustration, a contact hole that electrically connects the circuit pad PD-P and the circuit wiring SCL is formed in the circuit board PCB according to an embodiment of the inventive concept.

Each of the first circuit wiring SCL1 and the second circuit wiring SCL2 includes a conductive material. Each of the first circuit wiring SCL1 and the second circuit wiring SCL2 includes a metal, and, for example, each of the first circuit wiring SCL1 and the second circuit wiring SCL2 includes copper.

The first layer L1 includes a first insulating layer IL1 that covers the first circuit wiring SCL1. The second layer L2 includes a second insulating layer IL2 that covers the second circuit wiring SCL2.

Each of the first insulating layer IL1 and the second insulating layer IL2 includes an insulating material. Each of the first insulating layer IL1 and the second insulating layer IL2 includes an organic insulating material, and constituent materials of each of the first insulating layer IL1 and the second insulating layer IL2 include polymer materials such as one or more of polyimide (PI), polyethylene terephthalate (PET), or polyethylene naphthalate (PEN). For example, each of the first insulating layer IL1 and the second insulating layer IL2 includes polyimide (PI).

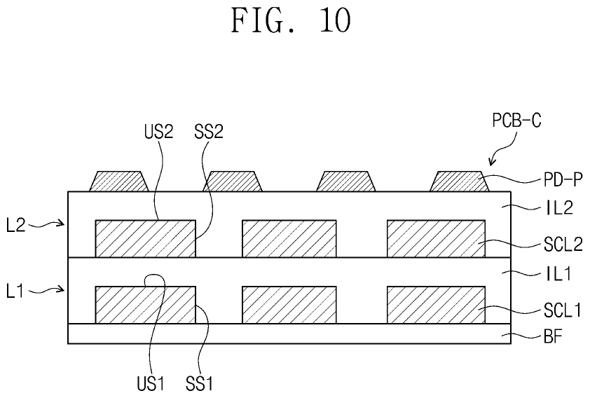

The second circuit wiring SCL2 and the corresponding first circuit wiring SCL1 are not vertically aligned with each other, and the second circuit wiring SCL2 and the corresponding first circuit wiring SCL1 do not partially overlap each other. When a plurality of wires is arranged side by side so that their sides match, as shown in the comparative example of FIG. 10, described below, there is a surface difference on the upper surface due to “space”. On the other hand, if the sides of a plurality of wires are not aligned vertically, as shown in FIG. 7A, the space between wires can be reduced, thereby reducing the surface difference. In an embodiment of the inventive concept, a first side SS1 of the first circuit wiring SCL1 overlaps at least a portion of an upper surface US2 of the second circuit wiring SCL2, or a second side SS2 of the second circuit wiring SCL2 overlaps at least a portion of an upper surface US1 of the first circuit wiring SCL1. In addition, even though the circuit board PCB according to an embodiment of the inventive concept includes a stack structure of the first circuit wiring SCL1 and the second circuit wiring SCL2, each of the first layer L1 and the second layer L2 includes a flat upper surface. As each of the first layer L1 and the second layer L2 includes a flat upper surface, process efficiency of connecting the circuit pad PD-P and the display pad PD-D disposed on the first and second layers L1 and L2 may be increased.

In addition, at least a portion of the first circuit wiring SCL1 extends in the first direction DR1, and the first side SS1 of the first circuit wiring SCL1 is one of the sides separated in the second direction DR2. At least a portion of the second circuit wiring SCL2 extends in the first direction DR1, and the second side SS2 of the second circuit wiring SCL2 is one of the sides separated in the second direction DR2.

The first side SS1 of the first circuit wiring SCL1 is not aligned in the third direction DR3 with the corresponding second side SS2 of the second circuit wiring SCL2. The first side SS1 of the first circuit wiring SCL1 includes a (1-1)-th side SS1-1 and a (1-2)-th side SS1-2 opposite to the (1-1)-th side SS1-1. The second side SS2 of the second circuit wiring SCL2 includes a (2-1)-th side SS2-1 and a (2-2)-th side SS2-2 opposite to the (2-1)-th side SS2-1. For example, the (1-1)-th side SS1-1 and the (2-1)-th side SS2-1 that corresponds to the (1-1)-th side SS1-1 are not aligned, and the (1-2)-th side SS2-1 and the (2-2)-th side SS2-2 that corresponds to the (2-1)-th side SS1-2 are not aligned.

In an embodiment, a first width W1 in the second direction DR2 of the first circuit wiring SCL1 differs from a second width W2 in the second direction DR2 of the corresponding second circuit wiring SCL2. Accordingly, the first side SS1 of the first circuit wiring SCL1 and the corresponding second side SS2 of the second circuit wiring SCL2 are not aligned.

The first circuit wiring SCL1 includes a (1-1)-th circuit wiring SCL1-1 and a (1-2)-th circuit wiring SCL2-2 spaced apart from the 1-1 circuit wiring SCL1-1 in the second direction DR2, and the second circuit wiring SCL2 includes a (2-1)-th circuit wiring SCL2-1 and a (2-2)-th circuit wiring SCL2-2 spaced apart from the (2-1)-th circuit wiring SCL2-1 in the second direction DR2. For example, a predetermined separation space is provided between the (1-1)-th circuit wiring SCL1-1 and the (1-2)-th circuit wiring SCL1-2 in the first layer L1. A predetermined separation space is provided between the (2-1)-th circuit wiring SCL2-1 and the (2-2)-th circuit wiring SCL2-2 in the second layer L2. At least a portion of the separation space between wirings in the first layer L1 and the separation space between wirings in the second layer L2 do not overlap.

In an embodiment, a first distance D1 between the (1-1)-th circuit wiring SCL1-1 and the (1-2)-th circuit wiring SCL1-2 differs from a distance D2 between the (2-1)-th circuit wiring SCL2-1 and the (2-2)-th circuit wiring SCL2-2. Accordingly, the first side SS1 of the first circuit wiring SCL1 is not aligned with the corresponding second side SS2 of the second circuit wiring SCL2.

Referring to FIGS. 7A to 7C, an imaginary center line IR1 of the first circuit wiring SCL1 that extends along the first direction DR1 does not overlap an imaginary center line IR2 of the second circuit wiring SCL2 that extends along the first direction DR1. Accordingly, the first side SS1 of the first circuit wiring SCL1 is not aligned with the corresponding second side SS2 of the second circuit wiring SCL2. The imaginary center lines IR1 and IR2 of each of the circuit wirings SCL1 and SCL2 are defined as center lines of the upper surfaces US1 and US2 of each of the first and second circuit wirings SCL1 and SCL2.

In addition, FIGS. 6 to 7C show the stack structure of the circuit wiring SCL in the circuit board PCB in the connection region PA, but embodiments are not necessarily limited thereto, and the circuit board PCB according to another embodiment includes the first circuit wiring SCL1 and the second circuit wiring SCL2 in a non-connection region NPA in addition to the connection region PA.

The display device according to an embodiment of the inventive concept includes a circuit board that has a stacked structure of circuit wirings, and provides a flat circuit board that increases connection efficiency with a display panel and increases accuracy of electrical connection. When circuit wirings are stacked in multiple layers on a circuit board in a display device, a step can be generated due to a separation space between the circuit wirings in one layer. The display device according to an embodiment of the inventive concept provides a circuit board that has improved shock resistance by minimizing the generation of a step by stacking non-aligned circuit wirings on different layers on a circuit board. In addition, even when the circuit wirings are stacked in multiple layers, the circuit board according to an embodiment of the inventive concept provides a flat upper surface, so that circuit pads of the circuit board are mounted on a flat surface. Accordingly, when the circuit pad of the circuit board and the display pad of the display panel are electrically connected, contact efficiency between the pads is increased, electrical connectivity is increased, and a display device having increased reliability is thus provided.

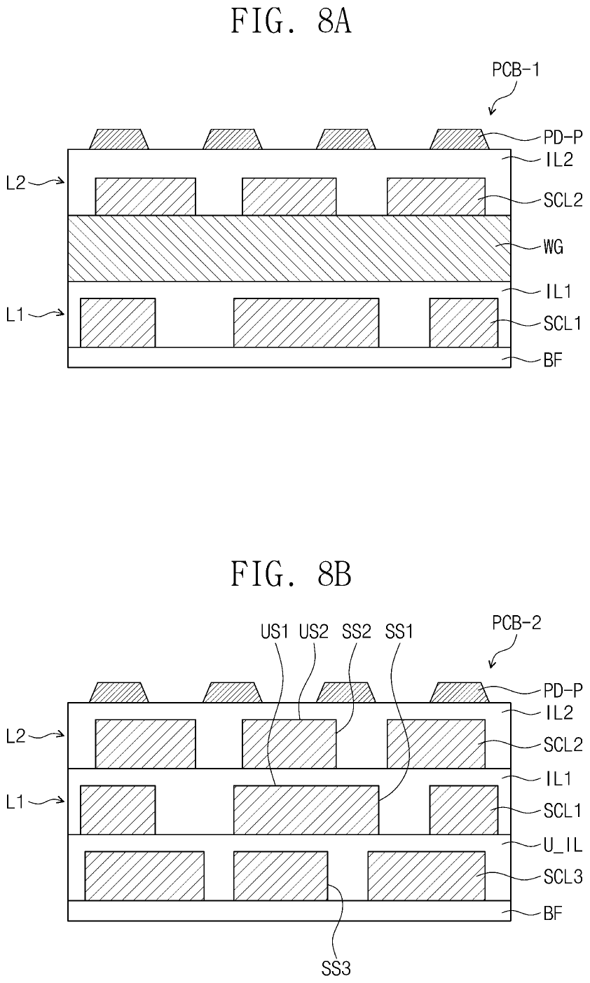

FIGS. 8A and 8B are each a cross-sectional view of a partial region of a circuit board according to another embodiment of the inventive concept. In the following description, the same/similar reference numerals may be used for the same/similar components as/to the components in FIGS. 6 to 7C, and redundant descriptions may be omitted.

Referring to FIG. 8A, in an embodiment, a circuit board PCB-1 further includes a planarization layer WG disposed between the first layer L1 and the second layer L2. The planarization layer WG entirely overlaps the first layer L1 and the second layer L2. The planarization layer WG includes a conductive material. For example, the planarization layer WG includes copper. The planarization layer WG is a ground wiring. The planarization layer WG provides a reference voltage, and thus serves as a ground. The planarization layer WG provides a reference potential for determining whether the circuit board PCB and elements mounted on the circuit board PCB operate. Although omitted for convenience of illustration from FIG. 8A, the circuit board PCB-1 according to an embodiment of the inventive concept includes an insulating layer disposed between the first layer L1 and the second layer L2, and the planarization layer WG is disposed on the insulating layer.

Referring to FIG. 8B, in an embodiment, a circuit board PCB-2 further includes a third circuit wiring SCL3 disposed below the first circuit wiring SCL1 and the second circuit wiring SCL2.

The third circuit wiring SCL3 is not vertically aligned with the corresponding first circuit wiring SCL1 or second circuit wiring SCL2, but at least partially overlaps the corresponding first circuit wiring SCL1 or second circuit wiring SCL2. Accordingly, the third side SS3 of the third circuit wiring SCL3 overlaps at least a portion of a first upper surface US1 of the first circuit wiring SCL1 or an upper surface US2 of the second circuit wiring SCL2. The third side SS3 of the third circuit wiring SCL3 is not aligned with the corresponding first side SS1 or second side SS2. The third side SS3 of the third circuit wiring SCL3 is one of the sides separated by the second direction DR2.

The circuit board PCB-2 further includes a lower insulating layer U_IL disposed between the base layer BF and the first insulating layer ILL. The lower insulating layer U_IL is disposed on the third circuit wiring SCL3 and covers the third circuit wiring SCL3.

The third circuit wiring SCL3 includes the same material as the first circuit wiring SCL1 or the second circuit wiring SCL2 described above, and the lower insulating layer U_IL includes the same material as the base layer BF, the first insulating layer IL1, or the second insulating layer IL2 described above.

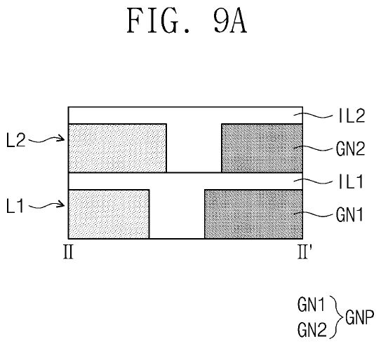

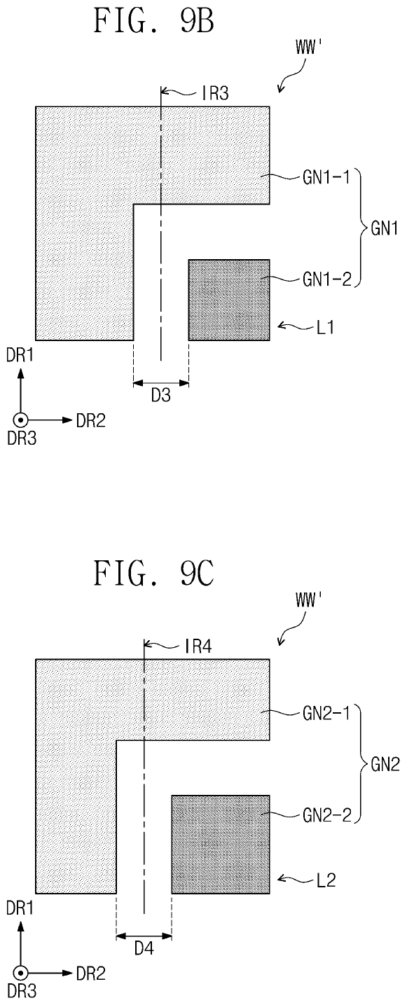

FIG. 9A is a cross-sectional view of a different partial region of a circuit board according to an embodiment of the inventive concept. FIG. 9A shows a cross-sectional view taken along line II-II′ in FIG. 5. FIG. 9B is a plan view of a different partial region of a first layer according to an embodiment of the inventive concept, and FIG. 9C is a plan view of a different partial region of a second layer according to an embodiment of the inventive concept. FIG. 9B is a plan view of the first layer in region WW′ shown in FIG. 5, and FIG. 9C is a plan view of the second layer in region WW′ shown in FIG. 5. FIGS. 9B and 9C show the relative positions of ground patterns GN1 and GN2 in each of a first layer L1 and a second layer L2 of the circuit board PCB in the non-connection region NPA. However, for convenience of illustration, an insulating layer, etc., are omitted in FIGS. 9B and 9C.

Referring to FIG. 9A, in an embodiment, the circuit board PCB includes a first layer L1 disposed on the base layer BF (see FIG. 7A) and a second layer L2 disposed on the first layer L1.

Each of the first layer L1 and the second layer L2 includes a ground wiring GNP. The first layer L1 includes a first ground wiring GN1, and the second layer L2 includes a second ground wiring GN2. However, embodiments of the inventive concept are not necessarily limited thereto, and in other embodiments, a single ground wiring GNP is provided, the ground wiring GNP is disposed on a layer parallel to the circuit pad PD-P (see FIG. 7A), or is disposed on the lower insulating layer U_IL (see FIG. 8B) described above.

Referring to FIGS. 9A to 9C, in an embodiment, the first ground wiring GN1 includes a (1-1)-th ground wiring GN1-1, and a (1-2)-th ground wiring GN1-2 spaced apart from the (1-1)-th ground wiring GN1-1. The second ground wiring GN2 includes a (2-1)-th ground wiring GN2-1, and a (2-2)-th ground wiring GN2-2 spaced apart from the (2-1)-th ground wiring GN2-1. When viewed in a plan view, the (1-1)-th ground wiring GN1-1 has an “L” shape that wraps around two sides of the (1-2)-th ground wiring GN1-2, which has a rectangular shape, and the a (2-1)-th ground wiring GN2-1 has an “L” shape that wraps around two sides of the (2-2)-th ground wiring GN2-2 which has a s rectangular shape. In an embodiment, each of the (1-2)-th ground wiring GN1-2 and the (2-2)-th ground wiring GN2-2 has a substantially square shape. However, the shape of each of the (1-1)-th ground wiring GN1-1 and the (1-2)-th ground wiring GN1-2 is not necessarily limited thereto and the shape of each of the (1-2)-th ground wiring GN1-2 and the (2-2)-th ground wiring GN2-2 is not necessarily limited thereto.

A predetermined separation space is provided between the (1-1)-th ground wiring GN1-1 and the (1-2)-th ground wiring GN1-2 in the first layer L1, and a predetermined separation space is provided between the (2-1)-th ground wiring GN2-1 and the (2-2)-th ground wiring GN2-2 in the second layer L2. At least a portion of the separation space between wirings in the first layer L1 and the separation space between wirings in the second layer L2 do not overlap. Accordingly, Since the first layer L1 and the second layer L2 provide a flat upper surface, the circuit board PCB according to an embodiment of the inventive concept has increased impact resistance.

A third distance D3 between the (1-1)-th ground wiring GN1-1 and the (1-2)-th ground wiring GN1-2 differs from a fourth distance D4 between the (2-1)-th ground wiring GN2-1 and the (2-2)-th ground wiring GN2-2. In addition, an imaginary center line IR3 of the separation space between the (1-1)-th ground wiring GN1-1 and the (1-2)-th ground wiring GN1-2 does not overlap an imaginary center line IR4 of the separation space between the (2-1)-th ground wiring GN2-1 and the (2-2)-th ground wirings GN2-2 when viewed in a plan view. The imaginary center line IR3 of the separation space between the (1-1)-th ground wiring GN1-1 and the (1-2)-th ground wiring GN1-2 is a center line of an imaginary upper surface of the separation space between the (1-1)-th ground wiring GN1-1 and the (1-2)-th ground wiring GN1-2. The imaginary center line IR4 of the separation space between the (2-1)-th ground wiring GN2-1 and the (2-2)-th ground wiring GN2-2 is a center line of an imaginary upper surface of the separation space between the (2-1)-th ground wiring GN2-1 and the (2-2)-th ground wirings GN2-2. The imaginary center lines IR3 and IR4 extend along the first direction DR1.

Referring to FIGS. 2 and 9A to 9C, each of the (1-1)-th wiring GN1-1 and the (2-1)-th ground wiring GN2-1 provide a reference potential for determining whether to operate an element related to the display panel DP. Each of the (1-1)-th wiring GN1-1 and the (2-1)-th ground wiring GN2-1 is connected to the display panel DP, and thus provides ground power related to the pixel pad D-PD (see FIG. 4A). Each of the (1-2)-th wiring GN1-2 and the (2-2)-th ground wiring GN2-2 provides a reference potential for determining whether to operate an element related to the input sensor ISP. Each of the (1-2)-th wiring GN1-2 and the (2-2)-th ground wiring GN2-2 is connected to the input sensor ISP, and thus provides a ground power to the input pad I-PD (see FIG. 4A).

Hereinafter, a display device according to an embodiment of the inventive concept will be described in detail with reference to evaluation results of the characteristics of examples and comparative examples, and FIGS. 7A and 10. In addition, the examples shown below are presented only for the understanding of the inventive concept, and the scope of the inventive concept is not limited thereto.

### Preparation of Examples and Comparative Examples

The example corresponds to a circuit board PCB manufactured to include a structure as shown in FIG. 7A. FIG. 10 is a cross-sectional view of a partial region of a circuit board according to a comparative example. FIG. 10 is a cross-sectional view of a circuit board PCB-C according to a comparative example shown to describe the effect of an embodiment of the inventive concept in detail. The comparative example corresponds to a circuit board PCB-C manufactured to include a structure shown in FIG. 10.

Referring to FIG. 7A, in an embodiment, in the circuit board PCB of an example, the first side SS1 of the first circuit wiring SCL1 and the second side SS2 of the second circuit wiring SCL2 are not vertically aligned. Accordingly, the first side SS1 overlaps at least a portion of the upper surface US2 of the second circuit wiring SCL2, and the second side SS2 overlaps at least a portion of the upper surface US1 of the first circuit wiring SCL1. In contrast, referring to FIG. 10, in the circuit board PCB-C of a comparative example, the first side SS1 of the first circuit wiring SCL1 and the second side SS2 of the second circuit wiring SCL2 are vertically aligned. Accordingly, the first side SS1 does not overlap the upper surface US2 of the second circuit wiring SCL2, and the second side SS2 does not overlap the upper surface US1 of the first circuit wiring SCL1.

### Comparison of Characteristics of Examples and Comparative Examples

To analyze the flatness of an example and a comparative example prepared as above, the profiles of the example and the comparative example were observed through a microscope. Table 1 presents the results and shows standard deviations for each thickness dispersion of the example and the comparative example observed through the microscope.

TABLE 1

| | Standard deviation in thickness |
|---|---|
| Example | 1.22 |
| Comparative Example | 2.42 |

Referring to the results of Table 2, the example has better flatness than the comparative example. Even when the circuit wirings are stacked in multiple layers, the example provides a flatter upper surface as compared to the comparative example, so that circuit pads of the circuit board can be mounted on a flatter surface.

A display device according to an embodiment of the inventive concept includes a circuit board that has a structure in which circuit wirings in a plurality of layers are not aligned. According to an embodiment of the inventive concept, even when a circuit board has a multi-layered structure, with the provision of a flat upper surface, the circuit board and a display panel in a display device have increased connection efficiency to provide a display device having increased reliability.

Therefore, according to an embodiment of the inventive concept, a display device that has increased reliability may be provided. Although embodiments of the present disclosure have been described with reference to the accompanying drawings, it will be understood that embodiments of the inventive concept should not be limited to the described embodiments but various changes and modifications may be made by those skilled in the art without departing from the spirit and scope of the present disclosure. Accordingly, the technical scope of embodiments of the inventive concept is not intended to be limited to the contents set forth in the detailed description of the specification, but is intended to be defined by the appended claims.

What is claimed is:

1. A display device, comprising:
a display panel that includes a plurality of display pads; and
a circuit board electrically connected to the display panel,
wherein the circuit board includes:
a base layer;
a first circuit wiring disposed on the base layer and that at least partially extends in a first direction;
a first insulating layer that covers the first circuit wiring;
a second circuit wiring disposed on the first insulating layer and that at least partially extends in the first direction;
a second insulating layer that covers the second circuit wiring; and
a plurality of circuit pads disposed on the second insulating layer and electrically connected to the plurality of display pads,
wherein a first side of the first circuit wiring overlaps at least a portion of an upper surface of the second circuit wiring, or a second side of the second circuit wiring overlaps at least a portion of an upper surface of the first circuit wiring.

2. The display device of claim 1, wherein the first side is not vertically aligned with the corresponding second side.

3. The display device of claim 2, wherein
the first side comprises a (1-1)-th side and a (1-2)-th side that faces the (1-1)-th side in a second direction that crosses the first direction,
the second side comprises a (2-1)-th side and a (2-2) side that faces the (2-1)-th side in the second direction,
the (1-1)-th side and the (2-1)-th side are not vertically aligned, and
the (1-2)-th side and the (2-1)-th are not vertically aligned.

4. The display device of claim 1, wherein an imaginary center line of the first circuit wiring parallel to the first direction does not overlap an imaginary center line of the second circuit wiring parallel to the first direction.

5. The display device of claim 1, wherein a width in a second direction that crosses the first direction of the first circuit wiring differs from a width in a second direction of the second circuit wiring.

6. The display device of claim 1, wherein the circuit board further comprises a lower insulating layer disposed between the base layer and the first insulating layer, and a third circuit wiring disposed on the lower insulating layer, wherein
a third side of the lower insulating layer is not vertically aligned with the first side or the second side.

7. The display device of claim 6, wherein the third side overlaps at least a portion of the upper surface of the first circuit wiring or the upper surface of the second circuit wiring.

8. The display device of claim 1, wherein one end of each of the first circuit wiring and the second circuit wiring is connected to the circuit pad.

9. The display device of claim 1, wherein the circuit board further comprises a planarization layer disposed between the first insulating layer and the second insulating layer.

10. The display device of claim 9, wherein the planarization layer comprises copper.

11. The display device of claim 1, wherein
the first circuit wiring comprises a (1-1)-th circuit wiring and a (1-2)-th circuit wiring spaced apart from the (1-1)-th circuit wiring in a second direction that crosses the first direction, and
the second circuit wiring comprises a (2-1)-th circuit wiring and a (2-2)-th circuit wiring spaced apart from the (2-1)-th circuit wiring in the second direction.

12. The display device of claim 11, wherein a shortest distance in the second direction between the (1-1)-th circuit wiring and the (1-2)-th circuit wiring differs from a shortest distance in the second direction between the (2-1)-th circuit wiring and the (2-2)-th circuit wiring.

13. The display device of claim 1, wherein the circuit board further comprises:
a first ground wiring disposed on the base layer and spaced apart from the first circuit wiring; and
a second ground wiring disposed on the first insulating layer and spaced apart from the second circuit wiring.

14. The display device of claim 13, wherein
the first ground wiring comprises a (1-1)-th ground wiring and a (1-2)-th ground wiring spaced apart from the (1-1)-th ground wiring, and
the second ground wiring comprises a (2-1)-th ground wiring and a (2-2)-th ground wiring spaced apart from the (2-1)-th ground wiring.

15. The display device of claim 14, further comprising an input sensor disposed on the display panel and that includes a sensing electrode,
wherein each of the (1-1)-th ground wiring and the (2-1)-th ground wiring is connected to the display panel, and each of the (1-2)-th ground wiring and the (2-2)-th ground wiring is connected to the input sensor.

16. The display device of claim 14, wherein an imaginary center line of a separation space located between the (1-1)-th ground wiring and the (1-2)-th ground wiring and that extends parallel to the first direction does not overlap an imaginary center line of a separation space located between the (2-1)-th ground wiring and the (2-2)-th ground wiring and that extends parallel to the first direction.

17. The display device of claim 14, wherein a shortest distance in a second direction that crosses the first direction between the (1-1)-th ground wiring and the (1-2)-th ground wiring differs from a shortest distance between the (2-1)-th ground wiring and the (2-2)-th ground wiring in the second direction.

18. The display device of claim 1, wherein the display panel comprises a first non-bendable region that includes a display region, a second non-bendable region, and a bendable region disposed between the first non-bendable region and the second non-bendable region and that has a predetermined radius of curvature, and
the circuit board overlaps the second non-bendable region.

19. The display device of claim 1, wherein
each of the first circuit wiring and the second circuit wiring comprises copper, and
each of the first insulating layer and the second insulating layer comprises polyimide (PI).

20. A display device, comprising:
a display panel; and
a circuit board electrically connected to the display panel,
wherein the circuit board includes:
a base layer;
a first circuit wiring disposed on the base layer and that extends in a first direction;
a first insulating layer that covers the first circuit wiring;
a second circuit wiring disposed on the first insulating layer and that extends in the first direction; and
a second insulating layer that covers the second circuit wiring, wherein
an imaginary center line of the first circuit wiring that extends parallel to the first direction does not overlap an imaginary center line of the second circuit wiring that extends parallel to the first direction.
